(19) United States
(12) Patent Application Publication
(10) Pub. No.: US 2009/0103350 A1
(43) Pub. Date: Apr. 23, 2009

(54) Method of Testing an Integrated Circuit, Method of Manufacturing an Integrated Circuit, and Integrated Circuit

(76) Inventor: Michael Kund, Tuntenhausen (DE)

Correspondence Address: SLATER & MATSIL, L.L.P., 17950 PRESTON ROAD, SUITE 1000, DALLAS, TX, 75252, US

(21) Appl. No.: 11/874,768

(22) Filed: Oct. 18, 2007

(51) Int. Cl. G11C 11/00; G11C 29/00; H01L 21/66

(52) U.S. Cl. 365/148; 365/201; 438/14; 257/E21.521

(57) ABSTRACT

According to one embodiment of the present invention, a method of testing a memory device including a memory cell array is provided, the method including: dividing the memory cell array into a plurality of memory cell array subunits, each memory cell array subunit including a plurality of resistivity changing memory cells; simultaneously testing all resistivity changing memory cells of a memory cell array subunit using a common testing signal; and repeating the testing for all further memory cell array subunits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a solid electrolyte memory device set to a first switching state;

FIG. 1B shows a cross-sectional view of a solid electrolyte memory device set to a second switching state;

FIG. 2 shows a flow chart of a method of testing a memory device according to one embodiment of the present invention;

FIG. 3 shows a flow chart of a method of testing a memory device according to one embodiment of the present invention;

FIG. 4A shows a schematic top view of an integrated circuit according to one embodiment of the present invention;

FIG. 4B shows a schematic top view of an integrated circuit according to one embodiment of the present invention;

FIG. 5A shows a schematic drawing of a testing system for testing an integrated circuit;

FIG. 5B shows a schematic drawing of a testing system for testing an integrated circuit according to one embodiment of the present invention;

FIG. 6 shows a schematic drawing of an integrated circuit according to one embodiment of the present invention;

FIG. 7 shows a schematic drawing of an integrated circuit according to one embodiment of the present invention;

FIG. 8 shows a method of testing an integrated circuit according to one embodiment of the present invention;

FIG. 9A shows a memory module according to one embodiment of the present invention;

FIG. 9B shows a stacked memory module according to one embodiment of the present invention;

FIG. 10 shows a cross-sectional view of a phase changing memory cell;

FIG. 11 shows a schematic drawing of a memory device including resistivity changing memory cells;

FIG. 12A shows a cross-sectional view of a carbon memory cell set to a first switching state;

FIG. 12B shows a cross-sectional view of a carbon memory cell set to a second switching state;

FIG. 13A shows a schematic drawing of a resistivity changing memory cell; and

FIG. 13B shows a schematic drawing of a resistivity changing memory cell.

### DETAILED DESCRIPTION OF ILLUSTRATIVE EMBODIMENTS

According to one embodiment of the present invention, a method of testing a memory device including a memory cell array is provided, the method including: a) dividing the memory cell array into a plurality of memory cell array subunits, each memory cell array subunit including a plurality of resistivity changing memory cells; b) simultaneously testing all resistivity changing memory cells of a memory cell array subunit using a common testing signal, thereby generating a test result reflecting the memory states of the resistivity changing memory cells of the memory cell array subunit; and c) repeating b) for all further memory cell array subunits.

According to one embodiment of the present invention, a memory cell array subunit is deactivated if the test result for the resistivity changing memory cells of the memory cell array subunit does not match a target test result.

According to one embodiment of the present invention, a redundant memory cell array subunit is assigned to the deactivated memory cell array subunit.

According to one embodiment of the present invention, the testing is at least partially performed within the memory device.

According to one embodiment of the present invention, each memory cell array subunit includes a first testing signal terminal and a second testing signal terminal, wherein each memory cell includes a first electrode layer, a second electrode layer, and a resistivity changing layer disposed between the first electrode layer and the second electrode layer, wherein all first electrodes are connected to the first testing signal terminal, and wherein all second electrodes are connected to the second testing signal terminal.

According to one embodiment of the present invention, the common testing signal is a testing voltage applied between the first testing signal terminal and the second testing signal terminal.

According to one embodiment of the present invention, the common testing signal is a testing current routed from the first testing signal terminal to the second testing signal terminal.

According to one embodiment of the present invention, the total resistance of the resistivity changing memory cells of a memory cell array subunit is measured using the common testing signal.

According to one embodiment of the present invention, the first testing signal terminal is a common source line, and the second testing signal terminal is a word line.

According to one embodiment of the present invention, the number of resistivity changing memory cells of a memory cell array subunit is 4.

According to one embodiment of the present invention, a method of testing a memory device including a memory cell array including a plurality of multi-level resistivity changing memory cells is provided, the method including: a) dividing a memory cell array into a plurality of memory cell array subunits, each memory cell array subunit including a plurality of multi-level resistivity changing memory cells; b) testing a resistance level of a multi-level resistivity changing memory cell, thereby generating a test result reflecting the memory state of the resistivity changing memory cell; c) if the test result for the resistance level does not match a predetermined target test result, deactivating the resistance level for all multi-level resistivity changing memory cells belonging to the same memory cell array subunit as the multi-level resistivity changing memory cell that has been tested; d) repeating b) and c) for all further multi-level resistivity changing memory cells.

According to one embodiment of the present invention, all memory cells which are connected to the same bit line form one memory cell array subunit.

According to one embodiment of the present invention, all memory cells which are connected to the same word line form one memory cell array subunit.

According to one embodiment of the present invention, each memory cell array subunit includes a first testing signal terminal and a second testing signal terminal, wherein each memory cell includes a first electrode layer, a second electrode layer, and a resistivity changing layer disposed between the first electrode layer and the second electrode layer, wherein all first electrodes are connected to the first testing signal terminal, and wherein all second electrodes are connected to the second testing signal terminal.

According to one embodiment of the present invention, the testing is carried out using a common testing voltage applied between the first testing signal terminal and the second testing signal terminal.

According to one embodiment of the present invention, the testing is carried out using a common testing current routed from the first testing signal terminal to the second testing signal terminal.

According to one embodiment of the present invention, the total resistance of the resistivity changing memory cells of a memory cell array subunit is measured using the common testing voltage or the common testing current.

According to one embodiment of the present invention, the deactivation is achieved by storing deactivation information within a deactivation information storing element.

According to one embodiment of the present invention, the deactivation information storing element is a latch.

According to one embodiment of the present invention, the number of resistance levels of the multi-level resistivity changing memory cells is 4.

According to one embodiment of the present invention, the resistance level which is tested is a resistance level between a highest possible resistance level and a lowest possible resistance level.

According to one embodiment of the present invention, the testing is at least partially performed within the memory device.

According to one embodiment of the present invention, an integrated circuit is provided, including: a memory cell array including a plurality of resistivity changing memory cells; testing functionality for carrying out a method of testing the memory cell array, the method including: a) dividing the memory cell array into a plurality of memory cell array subunits, each memory cell array subunit including a plurality of resistivity changing memory cells; b) simultaneously testing all resistivity changing memory cells of a memory cell array subunit using a common testing signal, thereby generating a test result reflecting the memory states of the resistivity changing memory cells of the memory cell array subunit; c) repeating b) for all further memory cell array subunits.

According to one embodiment of the present invention, the integrated circuit is arranged such that testing information reflecting the result of the testing is derivable from the integrated circuit via a single pin connected to the integrated circuit.

According to one embodiment of the present invention, the resistivity changing memory cells are programmable metallization cells.

According to one embodiment of the present invention, the resistivity changing memory cells are solid electrolyte memory cells.

According to one embodiment of the present invention, the resistivity changing memory cells are phase changing memory cells.

According to one embodiment of the present invention, the resistivity changing memory cells are carbon memory cells.

According to one embodiment of the present invention, an integrated circuit is provided, including: a memory cell array including a plurality of resistivity changing memory cells; functionality for carrying out a method of testing the memory cell array, the method including: a) dividing a memory cell array into a plurality of memory cell array subunits, each memory cell array subunit including a plurality of multi-level resistivity changing memory cells; b) testing a resistance level of a multi-level resistivity changing memory cell, thereby generating a test result reflecting the memory state of the resistivity changing memory cell; c) if the test result for the resistance level does not match a target test result, deactivating the resistance level for all multi-level resistivity changing memory cells belonging to the same memory cell array subunit as the multi-level resistivity changing memory cell that has been tested; d) repeating b) and c) for all further multi-level resistivity changing memory cells.

According to one embodiment of the present invention, the integrated circuit is arranged such that testing information reflecting the result of the testing is derivable from the integrated circuit via a single pin connected to the integrated circuit.

According to one embodiment of the present invention, a memory module is provided, including at least one integrated circuit including: a memory cell array including a plurality of resistivity changing memory cells; functionality for carrying out a method of testing the memory cell array, the method including: a) dividing the memory cell array into a plurality of memory cell array subunits, each memory cell array subunit including a plurality of resistivity changing memory cells; b) simultaneously testing all resistivity changing memory cells of a memory cell array subunit using a common testing signal, thereby generating a test result reflecting the memory states of the resistivity changing memory cells of the memory cell array subunit; c) repeating b) for all further memory cell array subunits.

According to one embodiment of the present invention, a memory module is provided including at least one integrated circuit including: a memory cell array including a plurality of resistivity changing memory cells; functionality for carrying out a method of testing the memory cell array, the method including: a) dividing a memory cell array into a plurality of memory cell array subunits, each memory cell array subunit including a plurality of multi-level resistivity changing memory cells; b) testing a resistance level of a multi-level resistivity changing memory cell, thereby generating a test result reflecting the memory states of the resistivity changing memory cells of the memory cell array subunit; c) if the test result for the resistance level does not match a target test result, deactivating the resistance level for all multi-level resistivity changing memory cells belonging to the same memory cell array subunit as the multi-level resistivity changing memory cell that has been tested; d) repeating b) and c) for all further multi-level resistivity changing memory cells.

According to one embodiment of the present invention, the memory module is stackable.

According to one embodiment of the present invention, a method of manufacturing an integrated circuit including a memory cell array including a plurality of resistivity changing memory cells is provided, the method including the following testing procedure: a) dividing the memory cell array into a plurality of memory cell array subunits, each memory cell array subunit including a plurality of resistivity changing memory cells; b) simultaneously testing all resistivity changing memory cells of a memory cell array subunit using a common testing signal, thereby generating a test result reflecting the memory states of the resistivity changing memory cells of the memory cell array subunit; c) repeating b) for all further memory cell array subunits.

According to one embodiment of the present invention, a method of manufacturing an integrated circuit including a memory cell array including a plurality of multi-level resistivity changing memory cells is provided, the method including the following testing procedure: a) dividing a memory cell array into a plurality of memory cell array subunits, each memory cell array subunit including a plurality of multi-level resistivity changing memory cells; b) testing a resistance level of a multi-level resistivity changing memory cell, thereby generating a test result reflecting the memory state of the resistivity changing memory cell; c) if the test result for the resistance level does not match a predetermined target test result, deactivating the resistance level for all multi-level resistivity changing memory cells belonging to the same memory cell array subunit as the multi-level resistivity changing memory cell that has been tested; d) repeating b) and c) for all further multi-level resistivity changing memory cells.

According to one embodiment of the present invention, an integrated circuit made by an embodiment of a manufacturing method according to the present invention is provided.

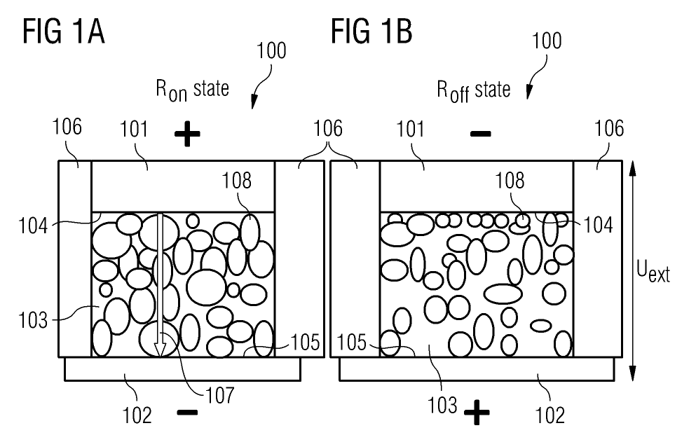

Since the embodiments of the present invention can be applied to programmable metallization cell devices (PMC) (e.g., solid electrolyte devices like CBRAM (conductive bridging random access memory) devices), in the following description, making reference to FIGS. 1A and 1B, a basic principle underlying embodiments of CBRAM devices will be explained.

As shown in FIG. 1A, a CBRAM cell 100 includes a first electrode 101, a second electrode 102, and a solid electrolyte block (in the following also referred to as ion conductor block) 103 which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may, for example, range between about 5 nm and about 500 nm. The thickness of the first electrode 101 may, for example, range between about 10 nm and about 100 nm. The thickness of the second electrode 102 may, for example, range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals. Alternatively, ion conductors that do not include a chalcogenide material may be used.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107. After having applied the voltage/inverse voltage, the memory cell 100 remains within the corresponding defined switching state even if the voltage/inverse voltage has been removed.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may, for example, represent “0”, whereas a low resistance represents “1”, or vice versa. The memory status detection may also be carried out using sensing voltages.

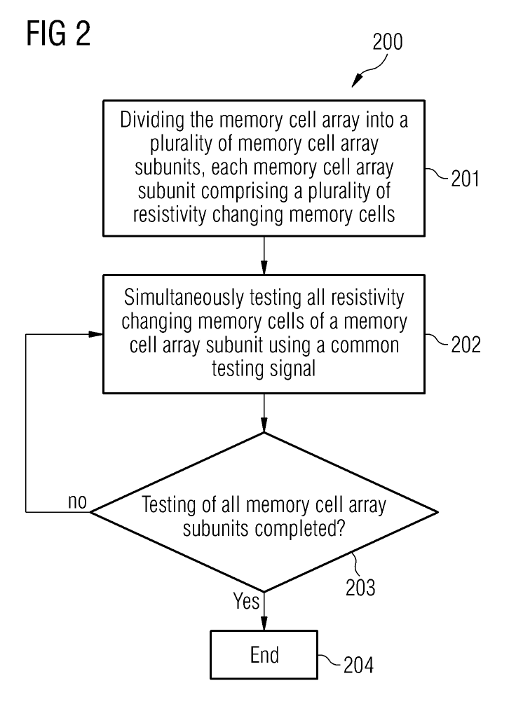

FIG. 2 shows a method 200 of testing a memory device including a memory cell array according to one embodiment of the present invention.

At 201, the memory cell array is divided into a plurality of memory cell array subunits, wherein each memory cell array subunit includes a plurality of resistivity changing memory cells.

At 202, all resistivity changing memory cells of a memory cell array subunit are simultaneously tested using a common testing signal.

At 203, it is determined whether all memory cell array subunits have already been tested. If this is the case, the method 200 is terminated at 204. If this is not the case, the method 200 returns to 202.

One effect of the testing method 200 is that the resistivity changing memory cells of a memory cell array subunit do not have to be tested one by one. Instead, the resistivity changing memory cells of a memory cell array subunit are simultaneously tested using a common testing signal. Since a common testing signal is used, the amount of testing time and/or the amount of testing signals can be reduced.

According to one embodiment of the present invention, a test result reflecting the memory states of the memory cells of a memory cell array subunit is determined at 202. The memory cell array subunit is deactivated if the test result does not match a target test result.

According to one embodiment of the present invention, a redundant memory cell array subunit is assigned to the deactivated memory cell array subunit. This redundant memory cell array subunit may then be used instead of the deactivated memory cell array subunit.

According to one embodiment of the present invention, the testing method 200 is completely or at least partially performed within the memory device. A corresponding test result may be stored within the memory device. This enables an external device to test the memory device very fast. The only thing which has to be done is to read out the test result stored within the memory device.

According to one embodiment of the present invention, the testing method may be performed during the manufacturing process of the memory device, or after having manufactured the memory device.

According to one embodiment of the present invention, each memory cell array subunit includes a first testing signal terminal and a second testing signal terminal. Further, each memory cell includes a first electrode layer, a second electrode layer and a resistivity changing layer disposed between the first electrode layer and the second electrode layer. All first electrodes are connected to the first testing signal terminal, and all second electrodes are connected to the second testing signal terminal.

According to one embodiment of the present invention, the common testing signal is a testing voltage which, at 202, is applied between the first testing signal terminal and the second testing signal terminal. Alternatively, the common testing signal is a testing current which, at 202, is routed from the first testing signal terminal to the second testing signal terminal.

According to one embodiment of the present invention, the common testing signal is used at 202 in order to measure the total resistance of the resistivity changing memory cells of a memory cell array subunit. The total resistance of the resistivity changing memory cells of a memory cell array subunit thus measured may then be compared with a total resistance target value. If the measured total resistance matches the total resistance target value, the memory cell array subunit works as intended. Otherwise, the memory cell array subunit may be judged as being defective. Before measuring the total resistance of the resistivity changing memory cells of a memory cell array subunit, the resistivity changing memory cells may be set to predetermined resistance levels. For example, half of the resistivity changing memory cells may be set to a memory stage “1”, whereas half of the resistivity changing memory cells may be set to the memory state “0” (e.g., checker board pattern). If the total resistance measured does not match the target total resistance, this is an indication that at least one of the resistivity changing memory cells of the memory cell array subunit could not be set to the predetermined memory state, i.e., at least one resistivity changing memory cell is defective.

According to one embodiment of the present invention, the first testing signal terminal is a common source line (CSL), and the second testing signal terminal is a word line (WL).

According to one embodiment of the present invention, the number of resistivity changing memory cells of a memory cell array subunit is four. The embodiments of the present invention, however, are not limited to this value.

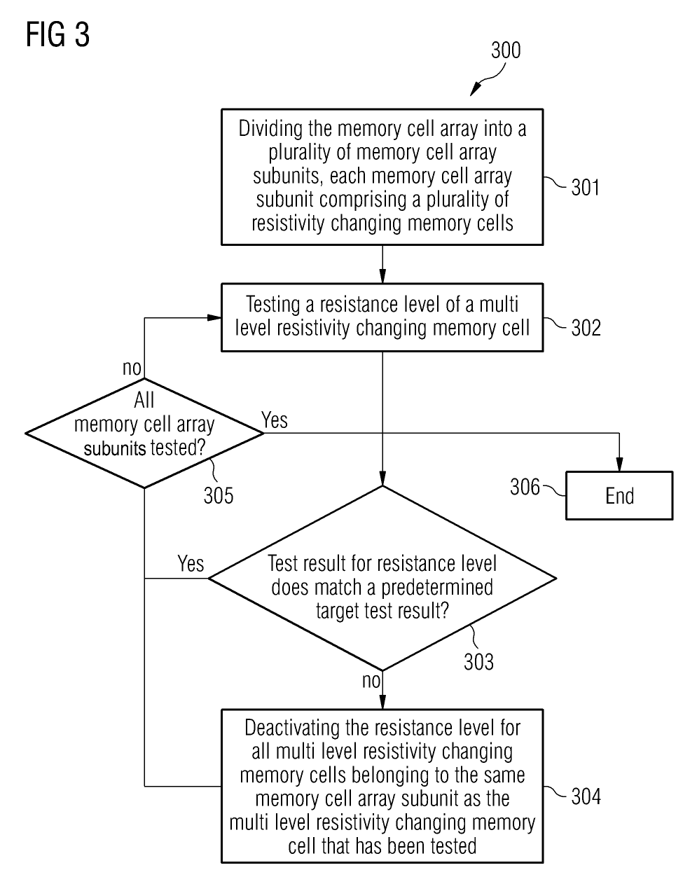

FIG. 3 shows a method 300 of testing a memory device or an integrated circuit including a memory cell array including a plurality of multi-level resistivity changing memory cells. The method includes the processes, detailed below.

At 301, the memory cell array is divided into a plurality of memory cell subunits, each memory cell subunit including a plurality of resistivity changing memory cells. At 302, a resistance level of a multi-level resistivity changing memory cell of a memory cell subunit is tested. At 303, it is tested whether the test result for the resistance level tested does match a predetermined target test result. If this is not the case, the resistance level is deactivated (i.e., the resistance level will not be further used) at 304 for all multi-level resistivity changing memory cells belonging to the same memory cell array subunit as the multi-level resistivity changing memory cell that has been tested. Then, the method 300 proceeds to 305. If the test result for the resistance level tested matched the predetermined target test result, the method 300 also proceeds to 305. At 305, it is determined whether all memory cell array subunits have already been tested. If this is the case, the method 300 is terminated at 306. Otherwise, the method returns to 302.

According to one embodiment of the present invention, the memory cell array includes a plurality of bit lines and a plurality of word lines. In this case, according to one embodiment of the present invention, all memory cells (or a part of all memory cells) which are connected to the same master bit line form one memory cell array subunit.

According to one embodiment of the present invention, each memory cell array subunit includes a first testing signal terminal and a second testing signal terminal. Further, each memory cell includes a first electrode layer, a second electrode layer and a resistivity changing layer disposed between the first electrode layer and the second electrode layer, wherein all first electrodes are connected to the first testing signal terminal, and wherein all second electrodes are connected to the second testing signal terminal.

According to one embodiment of the present invention, the testing method 300 is carried out using a common testing voltage (common testing signal) which, at 302, is applied between the first testing signal terminal and the second testing signal terminal. Alternatively, according to one embodiment of the present invention, the testing method 300 is carried out using a common testing current which, at 302, is routed from the first testing signal terminal to the second testing signal terminal.

According to one embodiment of the present invention, the total resistance of the resistivity changing memory cells of a memory cell array subunit is measured using the common testing voltage or the common testing current at 302.

According to one embodiment of the present invention, the deactivation at 304 is achieved by storing deactivation information within a deactivation information storing element within the memory device. The deactivation information storing element may, for example, be a latch.

According to one embodiment of the present invention, the number of resistance levels of the multi-level resistivity changing memory cells is four. The embodiments of the present invention, however, are not restricted to this value.

According to one embodiment of the present invention, the resistance level which is tested at 302 is a resistance level between a highest possible resistance level and a lowest possible resistance level.

As already mentioned in conjunction with the method 200 shown in FIG. 2, the method 300 may completely or only partially be performed within the memory device.

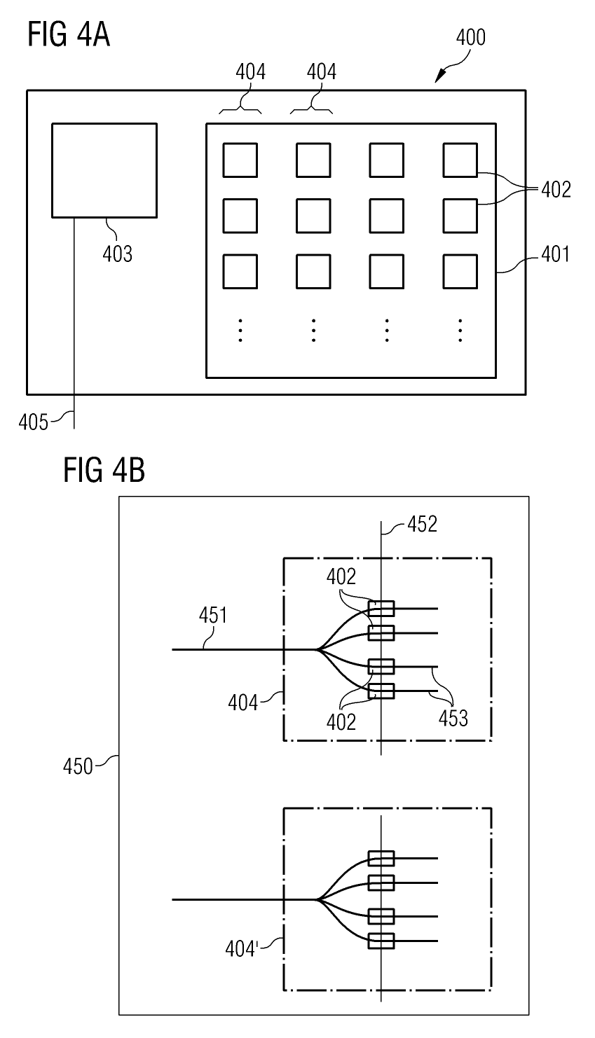

FIG. 4A shows an integrated circuit 400 according to one embodiment of the present invention. The integrated circuit 400 includes a memory cell array 401 including a plurality of resistivity changing memory cells 402. Further, the integrated circuit 400 includes functionality 403 (for example, a logic circuitry or a software program running within a digital signal processor) for carrying out a method of testing the memory cell array 401. The method includes: dividing the memory cell array 401 into a plurality of memory cell array subunits 404, wherein each memory cell array subunit 404 includes a plurality of resistivity changing memory cells 402. Here, the memory cell array subunits 404 are columns of resistivity changing memory cells 402. The memory cell array subunits 404 may include a desired number of resistivity changing memory cells 402 equal or larger than two. The method further includes simultaneously testing all resistivity changing memory cells 402 of a memory cell array subunit 404 using a common testing signal. The testing procedure described above is repeated for all further memory cell array subunits 404, i.e., until all resistivity changing memory cells 402 of the memory cell array 401 have been tested.

According to one embodiment of the present invention, the integrated circuit 400 is arranged such that testing information reflecting the result of the testing of the integrated circuit 400 is derivable from the integrated circuit 400 via a single pin 405 which is connected to the integrated circuit 400 (for example, connected to the testing functionality 403 as indicated in FIG. 4A or to another part of the integrated circuit 400).

According to one embodiment of the present invention, the resistivity changing memory cells 402 are programmable metallization cells (PMCs), also known as solid electrolyte memory cells (e.g., CBRAM-cells).

According to one embodiment of the present invention, the resistivity changing memory cells are phase changing memory cells (PC memory cells, e.g., PCRAM cells).

The embodiments of the present invention are not restricted to the types of resistivity changing memory cells 402 mentioned above. For example, organic memory cells (e.g., ORAM cells) or magneto resistive memory cells (e.g., MRAM cells) or transition metal oxide (TMO) memory cells may also be used.

According to one embodiment of the present invention, the testing functionality 403 may also be adapted to carry out the following method: dividing the memory cell array 401 into a plurality of memory cell array subunits 404, each memory cell array subunit 404 including a plurality of multi-level resistivity changing memory cells 402; testing a resistance level of a multi-level resistivity changing memory cell 402; if the test result for the resistance level does not match a target test result, deactivating the resistance level for all multi-level resistivity changing memory cells 402 belonging to the same memory cell array subunit 404 as the multi-level resistivity changing memory cell 402 that has been tested; and repeating the testing of the resistance level and the deactivation of defective multi-level resistivity changing memory cells 402 for all further multi resistivity changing memory cells 402.

FIG. 4B shows an integrated circuit 450 according to one embodiment of the present invention. The integrated circuit 450 includes a memory cell array subunit 404 including four resistivity changing memory cells 402. The memory cell array subunit 404 includes a first testing signal terminal 451 and a second testing signal terminal 452. Here, the first testing signal terminal 451 is a common source line (CSL) which is connected to, for example, four bit lines 453; the second testing signal terminal 452 is a word line. Each resistivity changing memory cell 402 includes a first electrode layer, a second electrode layer and a resistivity changing layer disposed between the first electrode layer and the second electrode layer, wherein all first electrodes are connected to the first testing signal terminal 451, and wherein all second electrodes are connected to the second testing signal terminal 452.

In order to test the resistivity changing memory cells 402, a common testing signal is used. For example, a common sensing current is routed from the first testing signal terminal 451 to the second testing signal terminal 452 via the bit lines 453 and the resistivity changing memory cells 402. The common testing current splits into four testing currents, each of the four testing currents being routed through one resistivity changing memory cell 402. The number of memory cells 402 which are simultaneously tested may, for example, be determined by the number of addresses used and the architecture of the integrated circuit 450. The number of memory cells 402 which are simultaneously tested is not restricted to four; also other numbers of memory cells 402 may be simultaneously tested. In this way, the total resistance of the arrangement of resistivity changing memory cells 402 shown in FIG. 4B is measured. Before the sensing currents are routed through the resistivity changing memory cells 402, the memory states of the resistivity changing memory cells 402 are set to predetermined resistance values. In this way, it can be sensed whether at least one of the resistivity changing memory cells 402 is defect (i.e., could not be switched into the predetermined memory state). In the embodiment shown in FIG. 4B it is assumed that the common testing signal supplied to the resistivity changing memory cells 402 is supplied via a common source line (CSL). However, an embodiment of the present invention is not restricted thereto; the common testing signal may also be applied to the resistivity changing memory cells 402 via another common line like a common word line.

If the total resistance measured does not match a predetermined target total resistance, the memory cell array subunit 404 is replaced by a redundant memory cell array subunit 404′ having the same architecture as that of the memory cell array subunit 404. Since the complete memory cell array subunit 404 is replaced by the redundant memory cell array subunit 404′, it is not necessary to know which particular resistivity changing memory cells 402 are defective. As a consequence, the number of testing time and/testing signals can be reduced.

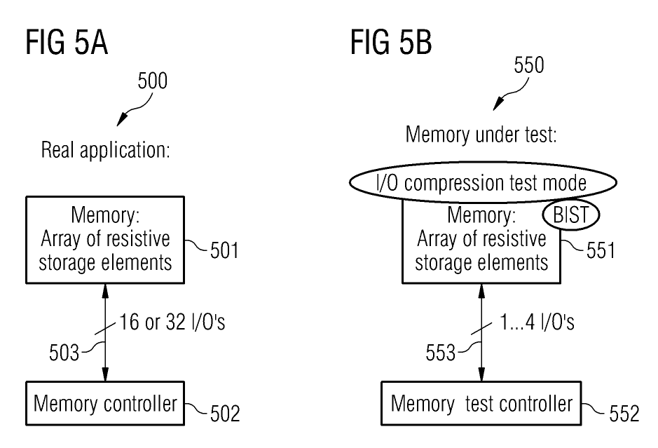

FIG. 5A shows an example of a system 500 including a memory device 501 and a memory controller 502 which is connected to the memory device 501 via a plurality of I/O's 503, e.g., via a plurality of pins. The memory device 501 includes an array of resistive storage elements. In order to use the memory device 501, the memory controller 502 communicates with the memory device 501 via I/O's. In this example, it is assumed that 16 or 32 I/O's are used in order to communicate between the memory controller 502 and the memory device 501. This way of communication may, for example, when executing a “normal” application on a computing device like an mp 3 player.

FIG. 5B shows a testing system 550 according to one embodiment of the present invention. The testing system 550 includes a memory device 551 and a memory device tester (memory controller) 552 which is electrically coupled to the memory device 551 via a plurality of I/O's 553, e.g., via a plurality of pins. The memory test controller 552 tests the memory device 551 by sending testing signals via the I/Os 553 to the memory device 551 and by receiving corresponding response signals. Compared to the system 500 shown in FIG. 5A, less I/O's are needed in order to carry out the communication between the memory device 551 and a memory device tester (memory controller) 552 during the testing since one common testing signal supplied via one of the I/O's 553 is used in order to simultaneously test a plurality of resistivity changing memory cells of the memory device 551. In this way, compared to a normal communication with the memory device 551, less I/O's are necessary. Here, only up to four I/O's are used. As a consequence, the complexity of the memory test controller 552 can be reduced. In the following description, the use of a reduced number of I/O's 553 (pins) is also referred to as I/O-compression test mode.

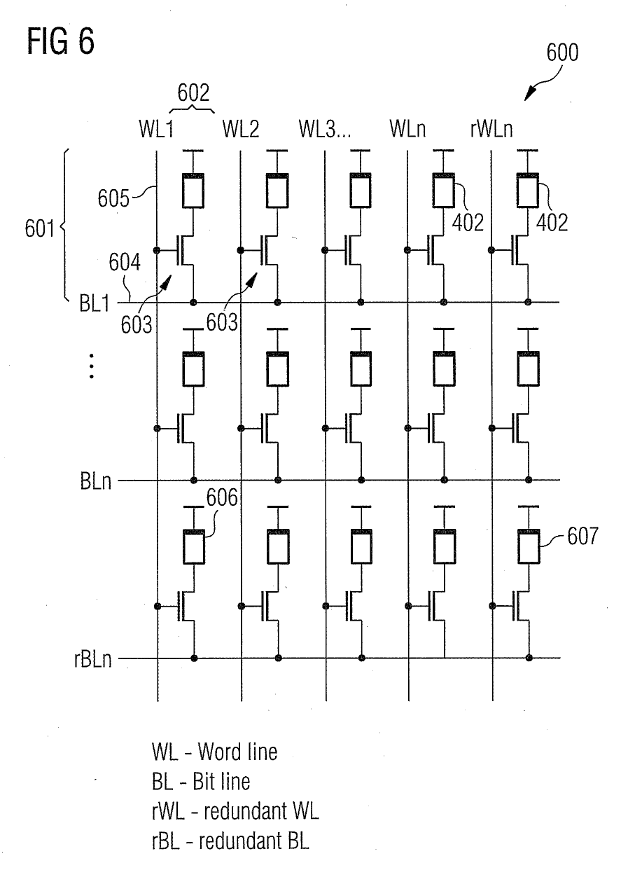

FIG. 6 shows a possible embodiment of a memory cell array 600 which may be used within an integrated circuit according to one embodiment of the present invention, for example, within the integrated circuit 400 shown in FIG. 4A. The memory cell array 600 includes a plurality of resistivity changing memory cells 402 which are arranged in rows 602 and columns 601. Each resistivity changing memory cell 402 is connected via a select device 603 to a bit line 604, wherein each select device 603 is controlled by a word line 605. The memory cell array 600 includes “normal” resistivity changing memory cells 402, select devices 603, bit lines 604 word lines 605 (here: word lines WL1 to WLn; bit lines BL1 to BLn and corresponding resistivity changing memory cells and select devices) and redundant resistivity changing memory cells 402, select devices 603, bit lines 604 and word lines 605 (here: word lines rWLn; bit lines rBLn and corresponding resistivity changing memory cells and select devices). If it is, for example, determined during the testing of the memory cell array 600 that the resistivity changing memory cell 606 is defective, it will be deactivated and “replaced” by the redundant resistivity changing memory cell 607, for example. That is, when addressing the resistivity changing memory cell 606, the address of the resistivity changing memory cell 606 may, for example, be mapped to the address of the redundant resistivity changing memory cell 607.

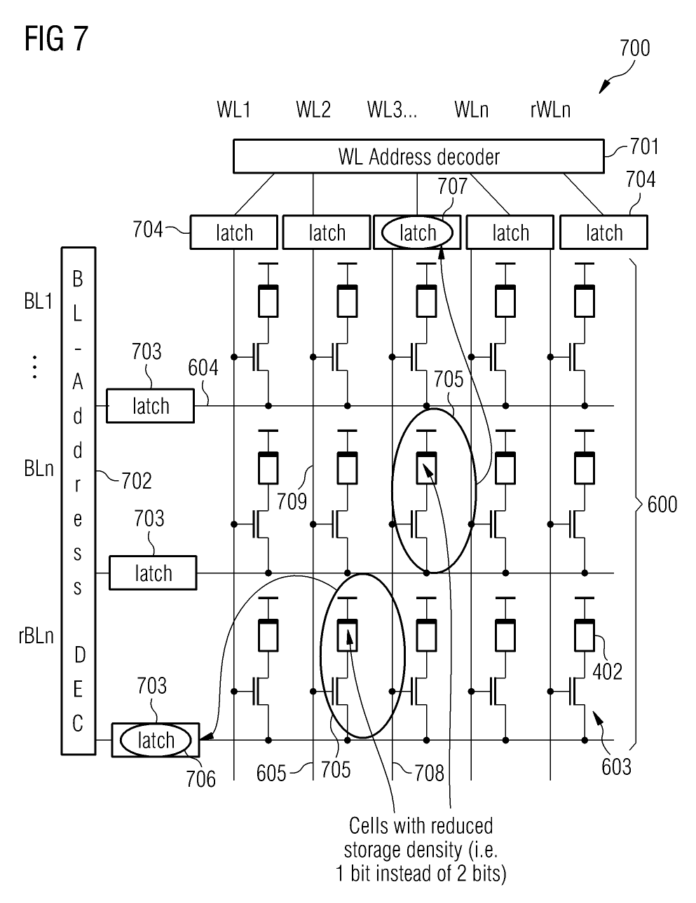

FIG. 7 shows an integrated circuit 700 including the memory cell array 600 shown in FIG. 6, a word line address decoder 701, a bit line address decoder 702, a plurality of first latches 703 which are connected between the bit line address decoder 702 and the bit lines 604, and a plurality of second latches 704 connected between the word line address decoders 701 and the word lines 605.

It is assumed here that the resistivity changing memory cells 402 of the memory cell array 600 are multi-level resistivity changing memory cells. In this case, instead of and/or in addition to “replacing” a defective resistivity changing memory cell 402 by an redundant resistivity changing memory cell 402, testing information may be stored within the first latches 703 or the second latches 704 indicating that one of the resistivity changing memory cells 402 which are assigned to the latch is defective, i.e., is not capable of adopting all resistance levels. The testing information effects all other resistivity changing memory cells belonging to the same latch 703, 704 that are partly deactivated, i.e., are only operated using the resistance levels which can also be used by the defective resistivity changing memory cell. For example, it is assumed that all resistivity changing memory cells 402 of the memory cell array 600 can adopt four different resistance levels. Further, it is assumed that the resistivity changing memory cells 705 can only adopt the first and the fourth resistance level, but not the second and/or the third resistance level, respectively. In this case, respective testing information indicating said defectiveness is stored within the latches 706 and 707. As a consequence, all resistivity changing memory cells 402 being connected to the word line 708 and the word line 709 are operated using only the first and fourth resistance level. In this way, a “replacement” of defect memory cells can be avoided.

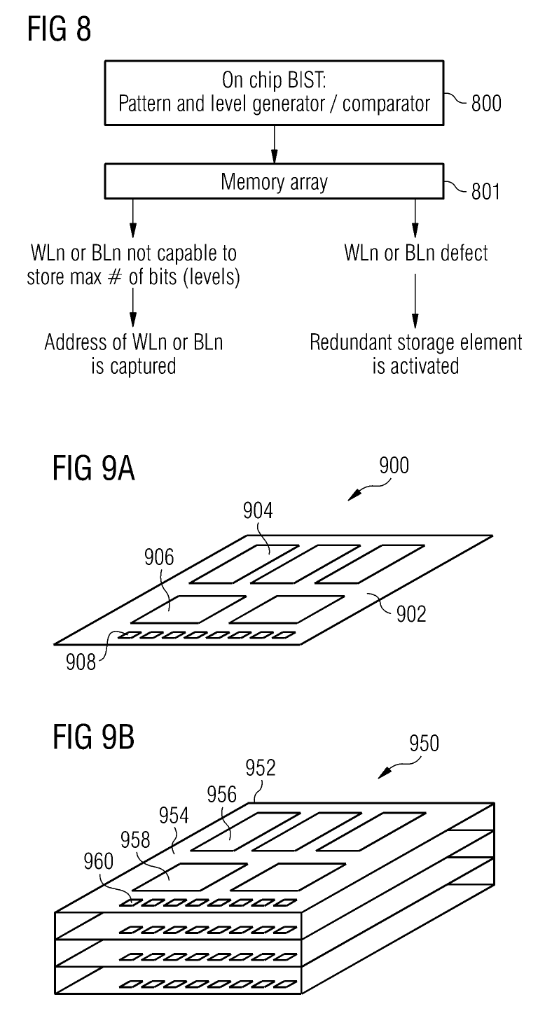

FIG. 8 indicates that, according to one embodiment of the present invention, two testing methods may be carried out in order to test a memory cell array. A built in self-test (BIST) unit 800 is used in order to generate a test pattern and corresponding test levels. Then, the actually written resistance levels are tested using a comparator. After having tested the memory cell array 801 as described above, there are two possibilities. A first possibility is to replace the defect resistivity changing memory cell by a redundant resistivity changing memory cell, i.e., to replace a memory cell array subunit including the defective resistivity changing memory cell by a corresponding redundant memory cell array subunit. A further possibility is (in the case multi-level resistivity changing memory cells are used) to capture the address of the memory cell array subunit including the defective resistivity changing memory cell and to deactivate the defect resistance level within all resistivity changing memory cells of the memory cell array subunit including the defective resistivity changing memory cell.

As shown in FIGS. 9A and 9B, in some embodiments, integrated circuits/memory devices such as those described herein may be used in modules. In FIG. 9A, a memory module 900 is shown, on which one or more integrated circuits/memory devices 904 according to one embodiment of the present invention are arranged on a substrate 902. The integrated circuit/memory device 904 may include numerous memory cells. The memory module 900 may also include one or more electronic devices 906, which may include memory, processing circuitry, control circuitry, addressing circuitry, bus interconnection circuitry, or other circuitry or electronic devices that may be combined on a module with a memory device, such as the integrated circuit/memory device 904. Additionally, the memory module 900 includes multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more integrated circuits/memory devices 956 according to one embodiment of the present invention, arranged on a stackable substrate 954. The integrated circuits/memory devices 956 contain memory cells. The stackable memory module 952 may also include one or more electronic devices 958, which may include memory, processing circuitry, control circuitry, addressing circuitry, bus interconnection circuitry, or other circuitry or electronic devices that may be combined on a module with a memory device, such as the integrated circuits/memory devices 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistivity of the resistivity changing memory cell, which represents the memory state of the memory cell.

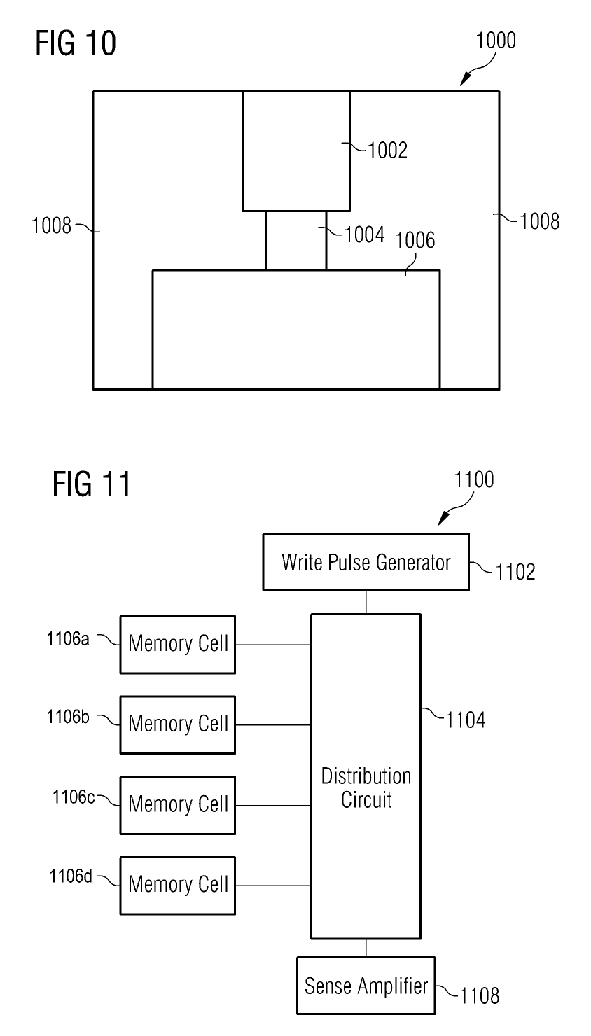

FIG. 10 illustrates a cross-sectional view of an exemplary phase changing memory cell 1000 (active-in-via type). The phase changing memory cell 1000 includes a first electrode 1002, a phase changing material 1004, a second electrode 1006, and an insulating material 1008. The phase changing material 1004 is laterally enclosed by the insulating material 1008. To use the phase changing memory cell in a memory cell, a selection device (not shown), such as a transistor, a diode, or another active device, may be coupled to the first electrode 1002 or to the second electrode 1006 to control the application of a current or a voltage to the phase changing material 1004 via the first electrode 1002 and/or the second electrode 1006. To set the phase changing material 1004 to the crystalline state, a current pulse and/or voltage pulse may be applied to the phase changing material 1004, wherein the pulse parameters are chosen such that the phase changing material 1004 is heated above its crystallization temperature, while keeping the temperature below the melting temperature of the phase changing material 1004. To set the phase changing material 1004 to the amorphous state, a current pulse and/or voltage pulse may be applied to the phase changing material 1004, wherein the pulse parameters are chosen such that the phase changing material 1004 is quickly heated above its melting temperature, and is quickly cooled.

The phase changing material 1004 may include a variety of materials. According to one embodiment, the phase changing material 1004 may include or consist of a chalcogenide alloy that includes one or more elements from group VI of the periodic table. According to another embodiment, the phase changing material 1004 may include or consist of a chalcogenide compound material, such as GeSbTe, SbTe, GeTe or AgInSbTe. According to a further embodiment, the phase changing material 1004 may include or consist of chalcogen free material, such as GeSb, GaSb, InSb, or GeGaInSb. According to still another embodiment, the phase changing material 1004 may include or consist of any suitable material including one or more of the elements Ge, Sb, Te, Ga, Bi, Pb, Sn, Si, P, O, As, In, Se, and S.

According to one embodiment, at least one of the first electrode 1002 and the second electrode 1006 may include or consist of Ti, V, Cr, Zr, Nb, Mo, Hf, Ta, W, or mixtures or alloys thereof. According to another embodiment, at least one of the first electrode 1002 and the second electrode 1006 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 11 illustrates a block diagram of a memory device 1100 including a write pulse generator 1102, a distribution circuit 1104, phase changing memory cells 1106a, 1106b, 1106c, 1106d (for example phase changing memory cells 1000 as shown in FIG. 10), and a sense amplifier 1108. According to one embodiment, a write pulse generator 1102 generates current pulses or voltage pulses that are supplied to the phase changing memory cells 1106a, 1106b, 1106c, 1106d via the distribution circuit 1104, thereby programming the memory states of the phase changing memory cells 1106a, 1106b, 1106c, 1106d. According to one embodiment, the distribution circuit 1104 includes a plurality of transistors that supply direct current pulses or direct voltage pulses to the phase changing memory cells 1106a, 1106b, 1106c, 1106d or to heaters being disposed adjacent to the phase changing memory cells 1106a, 1106b, 1106c, 1106d.

As already indicated, the phase changing material of the phase changing memory cells 1106a, 1106b, 1106c, 1106d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1108 is capable of determining the memory state of one of the phase changing memory cells 1106a, 1106b, 1106c, or 1106d in dependence on the resistance of the phase changing material.

To achieve high memory densities, the phase changing memory cells 1106a, 1106b, 1106c, 1106d may be capable of storing multiple bits of data, i.e., the phase changing material may be programmed to more than two resistance values. For example, if a phase changing memory cell 1106a, 1106b, 1106c, 1106d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 11 may also be applied in a similar manner to other types of resistivity changing memory cells like programmable metallization cells (PMCs), magento-resistive memory cells (e.g., MRAMs), organic memory cells (e.g., ORAMs), or transition oxide memory cells (TMOs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 4A and 4B.

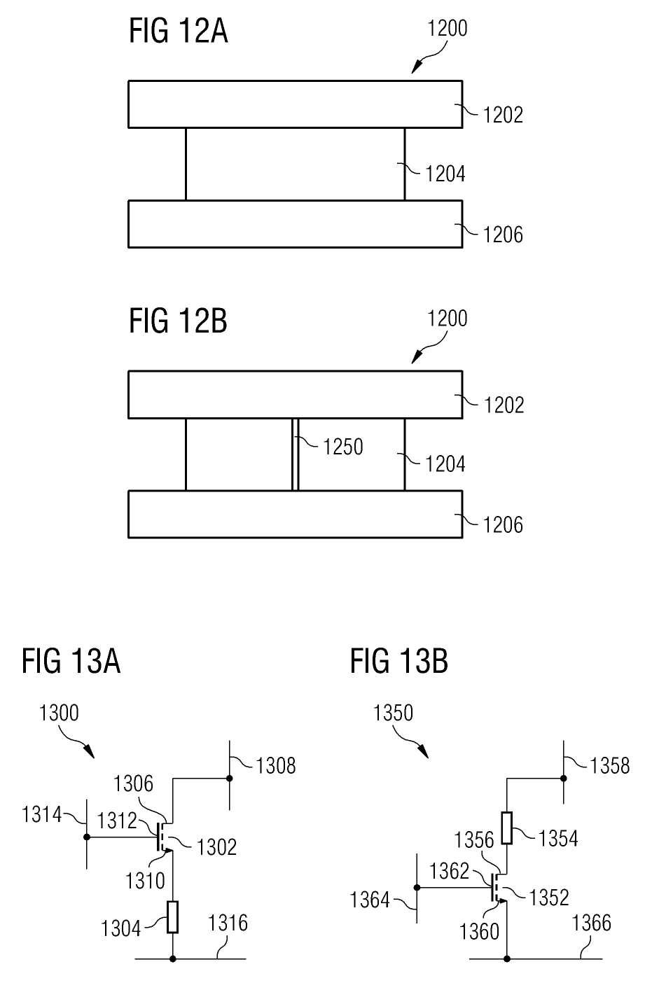

FIG. 12A shows a carbon memory cell 1200 that includes a top contact 1202, a carbon storage layer 1204 including an insulating amorphous carbon material rich in sp³-hybridized carbon atoms, and a bottom contact 1206. As shown in FIG. 12B, by forcing a current (or voltage) through the carbon storage layer 1204, an sp² filament 1250 can be formed in the sp³-rich carbon storage layer 1204, changing the resistivity of the memory cell. Application of a current (or voltage) pulse with higher energy (or, in some embodiments, reversed polarity) may destroy the sp² filament 1250, increasing the resistance of the carbon storage layer 1204. As discussed above, these changes in the resistance of the carbon storage layer 1204 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 13A shows a schematic representation of such a memory cell that uses a resistivity changing memory element. The memory cell 1300 includes a select transistor 1302 and a resistivity changing memory element 1304. The select transistor 1302 includes a source 1306 that is connected to a bit line 1308, a drain 1310 that is connected to the memory element 1304, and a gate 1312 that is connected to a word line 1314. The resistivity changing memory element 1304 also is connected to a common line 1316, which may be connected to ground, or to other circuitry, such as circuitry (not shown) for determining the resistance of the memory cell 1300, for use in reading. Alternatively, in some configurations, circuitry (not shown) for determining the state of the memory cell 1300 during reading may be connected to the bit line 1308. It should be noted that as used herein the terms connected and coupled are intended to include both direct and indirect connection and coupling, respectively.

To write to the memory cell 1300, the word line 1314 is used to select the memory cell 1300, and a current (or voltage) pulse on the bit line 1308 is applied to the resistivity changing memory element 1304, changing the resistance of the resistivity changing memory element 1304. Similarly, when reading the memory cell 1300, the word line 1314 is used to select the cell 1300, and the bit line 1308 is used to apply a reading voltage (or current) across the resistivity changing memory element 1304 to measure the resistance of the resistivity changing memory element 1304.

The memory cell 1300 may be referred to as a 1T1J cell, because it uses one transistor, and one memory junction (the resistivity changing memory element 1304). Typically, a memory device will include an array of many such cells. It will be understood that other configurations for a 1T1J memory cell, or configurations other than a 1T1J configuration may be used with a resistivity changing memory element. For example, in FIG. 13B, an alternative arrangement for a 1T1J memory cell 1350 is shown, in which a select transistor 1352 and a resistivity changing memory element 1354 have been repositioned with respect to the configuration shown in FIG. 13A. In this alternative configuration, the resistivity changing memory element 1354 is connected to a bit line 1358, and to a source 1356 of the select transistor 1352. A drain 1360 of the select transistor 1352 is connected to a common line 1366, which may be connected to ground, or to other circuitry (not shown), as discussed above. A gate 1362 of the select transistor 1352 is controlled by a word line 1364.

In the following description, further features of the embodiment of the present invention will be explained.

In some memory technologies, memory test costs can be estimated to be in the order of approximately 10% of the sales price. As the price for each piece of integrated silicon is rapidly decreasing, the test cost should decrease accordingly. There are (at least) two options to do so: a) decrease the test time or b) increase the number of devices under test (DUT) which are tested in parallel (at the same time). The first option can be achieved either with higher test speed (which in turn means higher cost for the test equipment) or less tests (which might result in less test coverage). Concerning the second option, it has to be mentioned that the number of tester channels (driver, receiver, power supplies, etc.) is limited.

According to one embodiment of the present invention, the number of pins (without the loss of information needed for repair of failing cells) for resistive switching memories is reduced (see FIG. 5).

According to one embodiment of the present invention, the multi-level-storage-capability and testing/repair of this, utilizing a built-in-self-test (generating the ML data and sensing them), is depicted.

According to one embodiment of the present invention, on chip compression of bits is used for resistive switching memories (MRAM, PCRAM, CBRAM, . . . ).

According to one embodiment of the present invention, internal testing of multi-bits/multi-levels (e.g., using a BIST (built in self test)) is performed.

According to one embodiment of the present invention, the fail addresses of certain memory elements (word line or bit line) with respect to MLC (multi-level cell) or MBC (i.e., in the address decoder, sense amplifier) are captured.

According to one embodiment of the present invention, for example, if one storage element of word line x is not able to store two bits but only one, this particular word line is not marked as defective (and replaced by a redundant element) but marked as ‘store one bit/cell’. This can also be done in a similar way for bit lines (see FIG. 7).

According to one embodiment of the present invention, a redundancy conform test mode for resistive switching memories is provided.

According to one embodiment of the present invention, the same test mode is used for multi-level testing (i.e., making use of a BIST, but can also be operated by an external tester).

According to one embodiment of the present invention, the fail addresses with respect to multi-level storage are captured (i.e., in the respective address decoder (word line and bit line)). Thus, cells with lower storage capacity (i.e., 1 bit instead of 2 bits) are not replaced by redundant elements. Instead of replacing them, only the maximum number of bits/levels which can be stored in the worst cell is stored in the whole word line or bit line, which may be carried out using a coding (in the sense amplifier and address decoder).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of testing a memory device comprising a memory cell array, the method comprising:
a) dividing the memory cell array into a plurality of memory cell array subunits, each memory cell array subunit comprising a plurality of resistivity changing memory cells;
b) simultaneously testing all resistivity changing memory cells of one of the memory cell array subunits using a common testing signal, thereby generating a test result reflecting memory states of the resistivity changing memory cells of the memory cell array subunit; and
c) repeating b) for all further memory cell array subunits.

2. The method according to claim 1, wherein a memory cell array subunit is deactivated if the test result for the resistivity changing memory cells of that memory cell array subunit does not match a target test result.

3. The method according to claim 2, further comprising assigning a redundant memory cell array subunit to the deactivated memory cell array subunit.

4. The method according to claim 1, wherein the testing is at least partially performed within the memory device.

5. The method according to claim 1, wherein each memory cell array subunit comprises a first testing signal terminal and a second testing signal terminal, and wherein each memory cell comprises a first electrode layer, a second electrode layer, and a resistivity changing layer disposed between the first electrode layer and the second electrode layer, wherein all first electrodes are connected to the first testing signal terminal, and wherein all second electrodes are connected to the second testing signal terminal.

6. The method according to claim 5, wherein the common testing signal is a testing voltage applied between the first testing signal terminal and the second testing signal terminal.

7. The method according to claim 5, wherein the common testing signal is a testing current routed from the first testing signal terminal to the second testing signal terminal.

8. The method according to claim 1, simultaneously testing comprises measuring a total resistance of the resistivity changing memory cells of the memory cell array subunit using the common testing signal.

9. The method according to claim 5, wherein the first testing signal terminal is a common source line, and the second testing signal terminal is a word line.

10. The method according to claim 1, wherein the number of resistivity changing memory cells of the memory cell array subunit is 4.

11. A method of testing a memory device comprising a memory cell array comprising a plurality of multi-level resistivity changing memory cells, the method comprising:
a) dividing the memory cell array into a plurality of memory cell array subunits, each memory cell array subunit comprising a plurality of multi-level resistivity changing memory cells;
b) testing a resistance level of the multi-level resistivity changing memory cell, thereby generating a test result reflecting a memory state of the resistivity changing memory cell;
c) if the test result for the resistance level does not match a predetermined target test result, deactivating the resistance level for all multi-level resistivity changing memory cells belonging to the same memory cell array subunit as the multi-level resistivity changing memory cell that has been tested; and
d) repeating b) and c) for all further multi-level resistivity changing memory cells.

12. The method according to claim 11, wherein all memory cells being connected to the same bit line form one memory cell array subunit.

13. The method according to claim 11, wherein all memory cells being connected to the same word line form one memory cell array subunit.

14. The method according to claim 11, wherein each memory cell array subunit comprises a first testing signal terminal and a second testing signal terminal, and wherein each memory cell comprises a first electrode layer, a second electrode layer, and a resistivity changing layer disposed between the first electrode layer and the second electrode layer, wherein all first electrodes are connected to the first testing signal terminal, and wherein all second electrodes are connected to the second testing signal terminal.

15. The method according to claim 14, wherein the testing is carried out using a common testing voltage applied between the first testing signal terminal and the second testing signal terminal.

16. The method according to claim 14, wherein the testing is carried out using a common testing current routed from the first testing signal terminal to the second testing signal terminal.

17. The method according to claim 16, comprising measuring a total resistance of the resistivity changing memory cells of the memory cell array subunit using the common testing voltage or the common testing current.

18. The method according to claim 11, wherein the deactivation is achieved by storing deactivation information within a deactivation information storing element.

19. The method according to claim 18, wherein the deactivation information storing element is a latch.

20. The method according to claim 11, wherein the number of resistance levels of the multi-level resistivity changing memory cells is 4.

21. The method according to claim 11, wherein the resistance level that is tested is a resistance level between a highest possible resistance level and a lowest possible resistance level.

22. The method according to claim 11, wherein the testing is at least partially performed within the memory device.

23. A method of manufacturing an integrated circuit, the method comprising:
a) forming a memory cell array comprising a plurality of resistivity changing memory cells;
b) dividing the memory cell array into a plurality of memory cell array subunits, each memory cell array subunit comprising a plurality of the resistivity changing memory cells;
c) simultaneously testing all resistivity changing memory cells of one of the memory cell array subunits using a common testing signal, thereby generating a test result reflecting memory states of the resistivity changing memory cells of the memory cell array subunit; and
d) repeating c) for all further memory cell array subunits.

24. An integrated circuit made by the method of claim 23.

25. A method of manufacturing an integrated circuit comprising, the method comprising:
a) forming a memory cell array comprising a plurality of multi-level resistivity changing memory cells;
b) dividing the memory cell array into a plurality of memory cell array subunits, each memory cell array subunit comprising a plurality of multi-level resistivity changing memory cells;
c) testing a resistance level of the multi-level resistivity changing memory cell, thereby generating a test result reflecting a memory state of the resistivity changing memory cell;
d) if the test result for the resistance level does not match a predetermined target test result, deactivating the resistance level for all multi-level resistivity changing memory cells belonging to the same memory cell array subunit as the multi-level resistivity changing memory cell that has been tested; and
e) repeating c) and d) for all further multi-level resistivity changing memory cells.
